(19) United States
(12) Patent Application Publication
(10) Pub. No.: US 2005/0269621 A1
(43) Pub. Date: Dec. 8, 2005

(54) Flash memory devices on silicon carbide

(75) Inventor: Leonard Forbes, Corvallis, OR (US)

Correspondence Address: LEFFERT JAY & POLGLAZE, P.A., P.O. BOX 581009, MINNEAPOLIS, MN, 55458-1009, US

(73) Assignee: Micron Technology, Inc.

(21) Appl. No.: 10/859,625

(22) Filed: Jun. 3, 2004

(51) Int. Cl. H01L 21/336

(52) U.S. Cl. 257/315

(57) ABSTRACT

A flash memory device is fabricated with a silicon carbide substrate. The substrate has doped source/drain regions for each memory transistor. A tunneling dielectric is formed above the substrate and substantially between the source drain regions. A floating gate is formed on top of the tunneling dielectric with an oxide inter-gate insulator on top of that. A control gate is formed on the inter-gate insulator. The floating gate can be comprised of either polycrystalline silicon or a microcrystalline silicon carbide.

### TECHNICAL FIELD OF THE INVENTION

The present invention relates generally to memory devices and in particular the present invention relates to flash memory device architecture.

### BACKGROUND OF THE INVENTION

Memory devices are typically provided as internal, semiconductor, integrated circuits in computers or other electronic devices. There are many different types of memory including random-access memory (RAM), read only memory (ROM), dynamic random access memory (DRAM), synchronous dynamic random access memory (SDRAM), and flash memory.

Flash memory devices have developed into a popular source of non-volatile memory for a wide range of electronic applications. Flash memory devices typically use a one-transistor memory cell that allows for high memory densities, high reliability, and low power consumption. Common uses for flash memory include personal computers, personal digital assistants (PDAs), digital cameras, and cellular telephones. Program code and system data such as a basic input/output system (BIOS) are typically stored in flash memory devices for use in personal computer systems.

The performance of flash memory devices needs to increase as the performance of computer systems increase. For example, a flash memory transistor that can be erased faster with lower voltages and have longer retention times could increase system performance.

For the reasons stated above, and for other reasons stated below which will become apparent to those skilled in the art upon reading and understanding the present specification, there is a need in the art for a higher performance flash memory transistor.

### SUMMARY

The above-mentioned problems with flash memory performance and other problems are addressed by the present invention and will be understood by reading and studying the following specification.

The present invention encompasses a flash memory transistor. The transistor is fabricated on a silicon carbide substrate that has a plurality of source/drain regions. The source/drain regions have a different conductivity than the remainder of the substrate. In one embodiment, the source/drain regions are n+ doped regions while the silicon carbide substrate is a p-type material. In two embodiments, the silicon carbide is either 4H—SiC or 6H—SiC.

A tunnel gate dielectric is formed overlying the substrate and substantially between the plurality of doped regions. The tunnel gate dielectric is a deposited oxide insulator.

A floating gate formed overlying the tunnel gate dielectric. The floating gate can be comprised of microcrystalline silicon carbide or polycrystalline silicon. An oxide, inter-gate insulator is formed overlying the floating gate. A control gate is formed on top of the inter-gate insulator. The control gate, in one embodiment, is a polysilicon material.

Further embodiments of the invention include methods and apparatus of varying scope.

### BRIEF DESCRIPTION OF THE DRAWINGS

FIG. 1 shows a cross-sectional view of a flash memory cell transistor of the present invention.

FIG. 2 shows a typical energy band diagram of silicon.

FIG. 3 shows an energy band diagram of 4H-silicon carbide in accordance with the present invention.

FIG. 4 shows a plot of tunneling current dependence on barrier height for various electric fields in accordance with the transistor structure of FIG. 1.

FIG. 5 shows a block diagram of an electronic system of the present invention.

### DETAILED DESCRIPTION

In the following detailed description of the invention, reference is made to the accompanying drawings that form a part hereof and in which is shown, by way of illustration, specific embodiments in which the invention may be practiced. In the drawings, like numerals describe substantially similar components throughout the several views. These embodiments are described in sufficient detail to enable those skilled in the art to practice the invention. Other embodiments may be utilized and structural, logical, and electrical changes may be made without departing from the scope of the present invention. The following detailed description is, therefore, not to be taken in a limiting sense, and the scope of the present invention is defined only by the appended claims and equivalents thereof.

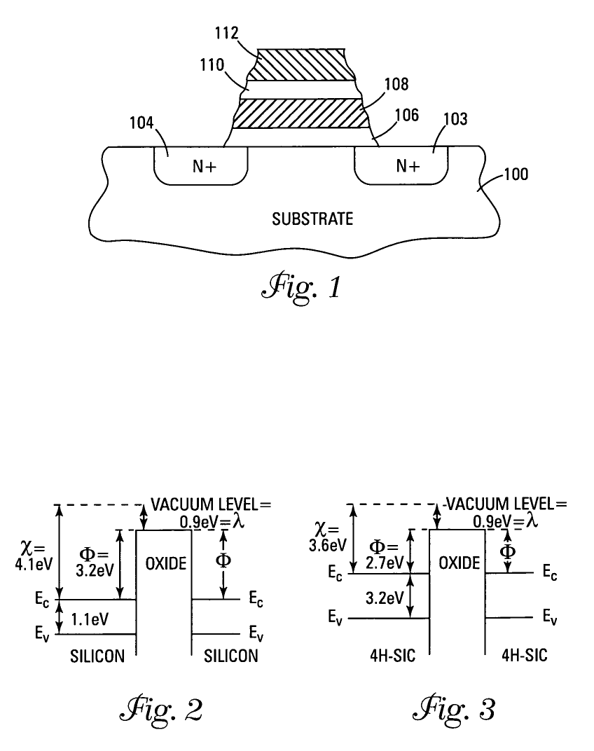

FIG. 1 illustrates a cross-sectional view of a flash memory cell transistor of the present invention. The transistor is fabricated on a 4H-silicon carbide (SiC) substrate instead of the silicon substrate of the prior art. In an alternate embodiment, 6H—SiC is used.

The SiC results in a lower electron affinity, χ, and a smaller tunneling barrier, Φ, than silicon. These relationships are illustrated in the energy band diagrams of FIGS. 2 and 3.

FIG. 2 illustrates the energy band diagram for a memory device using a silicon substrate while FIG. 3 illustrates the energy band diagram for a memory device with a silicon carbide substrate. The diagrams show the conduction band edge, E_{C}, and the valence band edge, E_{V}. Between E_{C} and E_{V} is the band gap where there are no states for electrons. The tunneling barrier, Φ, is the discontinuity in the conduction bands.

FIG. 2 shows that a typical silicon flash memory has an electron affinity of 4.1 eV and a barrier energy of 3.2 eV. FIG. 3 illustrates that 4H—SiC has X=3.6 eV and Φ=2.7 eV. As is well known in the art, the lower tunneling barrier results in an easier erase operation requiring lower voltages and electric fields.

Referring again to FIG. 1, the flash memory cell of the present invention is further comprised of two source/drain regions 103 and 104 that are doped into the SiC substrate 100. Which region 103 or 104 functions as source and which functions as drain is determined by the direction of operation of the transistor.

In one embodiment, the source/drain regions 103 and 104 are n+ doped regions in a p-type substrate 100. An alternate embodiment may use p+ doped source/drain regions in an n-type substrate. The present invention is not limited to any one conductivity type for the source/drain regions or the substrate.

A tunnel gate dielectric 106 is formed overlying the substrate 100 between the source/drain regions 103 and 104. In one embodiment, the floating gate 108 is a polycrystalline silicon floating gate layer 108 is formed on top of the tunnel gate dielectric layer 106. An alternate embodiment uses a microcrystalline silicon carbide floating gate 108.

An inter-gate oxide dielectric 110 is formed on top of the floating gate 108. In one embodiment, this layer is formed by a deposition process. A control gate 112 is formed on top of the inter-gate oxide dielectric 110. In one embodiment, the control gate 112 is comprised of a polysilicon material.

The lower tunneling barrier height of the SiC substrate/gate insulator junction provides larger tunneling current into the floating gate 108 with a smaller gate voltage. Additionally, larger tunneling current out of the floating gate 108 is accomplished with smaller control gate 112 voltages. Fowler-Nordheim tunneling can be used for write and erase operations since the electron mobility is lower for SiC than Si.

An embodiment using single crystalline SiC n-channel CMOS transistors and SiO gate insulators results in a lower tunneling barrier for channel hot electron injection onto the floating gate 108. An embodiment using microcrystalline floating gates results in a lower tunneling barrier and ease of erase. An embodiment using polycrystalline silicon gates results in larger erase barriers and longer retention times.

The conventional processing techniques that are used on silicon technology can be applied to SiC devices. These techniques include oxidation to form the tunnel gate dielectric, implantation of the source/drain regions, and deposition processes for the floating gate, inter-gate dielectric, and polysilicon control gate.

Metallization and patterning techniques that are commonly used in silicon technology can also be employed on SiC. The main difference is that SiC requires higher temperatures and longer oxidation times than Si processes. Additionally, higher temperatures are required for annealing and diffusion of impurities after implantation of the source/drain regions.

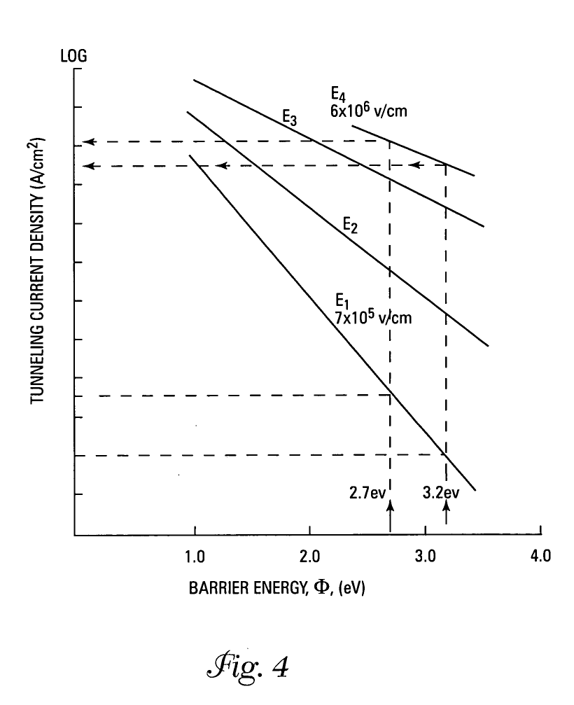

FIG. 4 illustrates the increased tunneling currents as a result of the lower barriers at the oxide interface for electrons at the surface of the crystalline 4H—SiC. The graph shows tunneling current density (Amps/cm 2) versus barrier energy (eV) for different electric field values (E1-E4), in volts/cm, in the gate insulator.

A reduction of the barrier from 3.2 eV of Si to 2.7 eV for SiC results in an increase in the tunneling current by orders of magnitude at the same electric field. In the case of microcrystalline SiC, even much lower barriers might be expected. SiC has many forms and the electron barrier with oxide on microcrystalline layers is probably lower than the 2.7 eV with the crystalline 4H—SiC. Lower barriers would result in an easier erase operation for the transistors of the present invention.

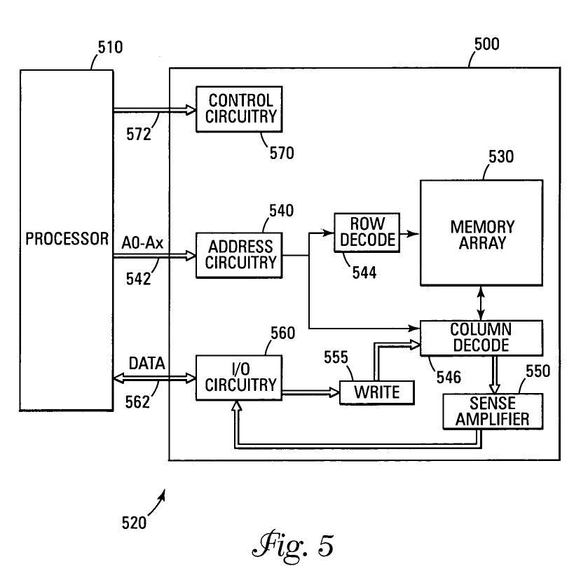

FIG. 5 illustrates a functional block diagram of a memory device 500 that can incorporate the flash memory cells of the present invention. The memory device 500 is coupled to a processor 510. The processor 510 may be a microprocessor or some other type of controlling circuitry. The memory device 500 and the processor 510 form part of an electronic system 520. The memory device 500 has been simplified to focus on features of the memory that are helpful in understanding the present invention.

The memory device includes an array of flash memory cells 530 that can be floating gate flash memory cells. The memory array 530 is arranged in banks of rows and columns. The control gates of each row of memory cells is coupled with a wordline while the drain and source connections of the memory cells are coupled to bitlines. As is well known in the art, the connection of the cells to the bitlines depends on whether the array is a NAND architecture or a NOR architecture.

An address buffer circuit 540 is provided to latch address signals provided on address input connections A0-Ax 542. Address signals are received and decoded by a row decoder 544 and a column decoder 546 to access the memory array 530. It will be appreciated by those skilled in the art, with the benefit of the present description, that the number of address input connections depends on the density and architecture of the memory array 530. That is, the number of addresses increases with both increased memory cell counts and increased bank and block counts.

The memory device 500 reads data in the memory array 530 by sensing voltage or current changes in the memory array columns using sense/buffer circuitry 550. The sense/buffer circuitry, in one embodiment, is coupled to read and latch a row of data from the memory array 530. Data input and output buffer circuitry 560 is included for bi-directional data communication over a plurality of data connections 562 with the controller 510. Write circuitry 555 is provided to write data to the memory array.

Control circuitry 570 decodes signals provided on control connections 572 from the processor 510. These signals are used to control the operations on the memory array 530, including data read, data write, and erase operations. The control circuitry 570 may be a state machine, a sequencer, or some other type of controller.

The flash memory device illustrated in FIG. 5 has been simplified to facilitate a basic understanding of the features of the memory. A more detailed understanding of internal circuitry and functions of flash memories are known to those skilled in the art.

### CONCLUSION

In summary, the flash memory transistors of the present invention are fabricated on a silicon carbide substrate with both microcrystalline SiC and polycrystalline floating gates. This provides reduced tunnel barrier and ease of erase with lower voltages and electric fields.

The flash memory cells of the present invention may be NAND-type cells, NOR-type cells, or any other type of flash memory array architecture.

Although specific embodiments have been illustrated and described herein, it will be appreciated by those of ordinary skill in the art that any arrangement that is calculated to achieve the same purpose may be substituted for the specific embodiments shown. Many adaptations of the invention will be apparent to those of ordinary skill in the art. Accordingly, this application is intended to cover any adaptations or variations of the invention. It is manifestly intended that this invention be limited only by the following claims and equivalents thereof.

1. A flash memory transistor comprising:
a silicon carbide substrate having a plurality of source/drain regions, the source/drain regions having a different conductivity than the remainder of the substrate;
a tunnel gate dielectric formed overlying the substrate and substantially between the plurality of doped regions;
a floating gate formed overlying the tunnel gate dielectric, the floating gate comprised of microcrystalline silicon carbide;
an inter-gate insulator formed overlying the floating gate; and
a control gate formed overlying the inter-gate insulator.

2. The transistor of claim 1 wherein the tunnel gate dielectric is comprised of silicon oxide.

3. The transistor of claim 1 wherein the control gate is comprised of polysilicon.

4. The transistor of claim 1 wherein the silicon carbide substrate is 4H-silicon carbide.

5. The transistor of claim 1 wherein the silicon carbide substrate is 6H-silicon carbide.

6. The transistor of claim 1 wherein the source/drain regions are n+ conductivity and the silicon carbide substrate is p+ conductivity.

7. The transistor of claim 1 wherein the control gate is comprised of a polysilicon material.

8. The transistor of claim 1 wherein a first source/drain region acts as a source and a second source/drain region acts as a drain in response to a direction of operation of the transistor.

9. A flash memory transistor comprising:
a silicon carbide substrate having a plurality of source/drain regions, the source/drain regions having a different conductivity than the remainder of the substrate;
a tunnel gate dielectric formed overlying the substrate and substantially between the plurality of doped regions;
a floating gate formed overlying the tunnel gate dielectric, the floating gate comprised of polycrystalline silicon;
an inter-gate insulator formed overlying the floating gate; and
a control gate formed overlying the inter-gate insulator.

10. The transistor of claim 9 wherein the inter-gate dielectric is formed by a deposition process and the tunnel gate dielectric is formed by an oxidation process.

11-20. (canceled)

21. A method for erasing a flash memory device on a silicon carbide substrate, the method comprising:
applying a positive voltage to a source region located in the silicon carbide substrate; and
applying a negative voltage to a control gate overlying the silicon carbide substrate in order to erase a silicon carbide floating gate.

22. A method for programming a flash memory device on a silicon carbide substrate, the method comprising:
applying a positive voltage to a control gate overlying the silicon carbide substrate; and
causing Fowler-Nordheim tunneling to occur from the source region to a silicon carbide floating gate.

23. An electronic system comprising:
a processor that generates control signals; and
a memory array coupled to the processor, the array comprising a plurality of flash memory cells, each flash memory cell comprising:
a silicon carbide substrate having a plurality of source/drain regions, the source/drain regions having a different conductivity than the remainder of the substrate;
a tunnel gate dielectric formed overlying the substrate and substantially between the plurality of doped regions;
a floating gate formed overlying the tunnel gate dielectric, the floating gate comprised of either a microcrystalline silicon carbide or a polycrystalline silicon;
an inter-gate insulator formed overlying the floating gate; and
a control gate formed overlying the inter-gate insulator.

24. The system of claim 23 wherein the plurality of source/drain regions are created with an n+ conductivity in a p+silicon carbide substrate.

25. The system of claim 23 wherein the memory array is comprised of a NAND-type architecture.

26. The system of claim 23 wherein the memory array is comprised of a NOR-type architecture.
